(19) United States
(12) Patent Application Publication
(10) Pub. No.: US 2025/0054930 A1
(43) Pub. Date: Feb. 13, 2025

(54) Integrated transceiver array

(71) Applicant: Apple Inc., Cupertino, CA (US)

(72) Inventors: Shingo Mandai, Mountain View, CA (US); Cristiano L. Niclass, San Jose, CA (US); Pengfei Sun, Santa Clara, CA (US); Vyshakh Sanjeev, San Francisco, CA (US)

(21) Appl. No.: 18/778,986

(22) Filed: Jul. 21, 2024

Related U.S. Application Data
(60) Provisional application No. 63/518,579, filed on Aug. 10, 2023.

(51) Int. Cl. H01L 25/16; G01S 17/34; G02B 6/12; G02B 6/42; G02B 6/43; H01L 23/00; H01L 27/144; H01L 31/02; H01L 31/0232; H01L 31/107; H01S 5/026; H01S 5/183

(52) U.S. Cl. CPC H01L 25/167; G02B 6/4245; G02B 6/43; H01L 24/08; H01L 27/144; H01L 31/02027; H01L 31/02327; H01L 31/107; H01S 5/0262; H01S 5/183; G01S 17/34; G02B 2006/12061; G02B 2006/12107; H01L 2224/08145; H01L 2924/12042; H01L 2924/1431

(57) ABSTRACT

An optoelectronic device includes a first semiconductor die, having first and second surfaces and including a first array of transceiver elements. Each transceiver element includes an optical transducer, which directs outgoing coherent optical radiation through the first surface toward a target and to receive incoming optical radiation that has been reflected from the target. A single-photon optical detector outputs electrical pulses in response to photons of the incoming optical radiation. A waveguide conveys the incoming optical radiation from the optical transducer to the single-photon optical detector. A second semiconductor die is bonded to the second surface of the first semiconductor die and includes a second array of logic circuits, which are coupled to receive and process the electrical pulses output by the single-photon optical detectors in corresponding ones of the transceiver elements.

### RELATED APPLICATIONS

This patent application claims the benefit of U.S. Provisional Patent Application 63/518,579, filed Aug. 10, 2023. This application is also related to U.S. patent application Ser. No. 18/623,080, filed Apr. 1, 2024. The disclosures of both these related applications are incorporated herein by reference.

### FIELD

The present invention relates generally to optoelectronic devices, and particularly to optical transceiver arrays.

### BACKGROUND

In frequency-modulated continuous-wave (FMCW) LiDAR sensing arrangements, a radio-frequency (RF) chirp is applied to modulate the frequency of a beam of optical radiation (typically a single-mode laser beam) that is directed toward a target. The optical radiation reflected from the target is mixed with a sample of the transmitted light, referred to as a “local oscillator” or “local beam.” The mixed optical radiation is detected by a photodetector, such as a balanced photodiode pair, which then outputs an RF signal comprising a beat frequency that is proportional to the distance to the target. When the target is moving, the resulting Doppler shift of the reflected optical radiation will cause the beat frequency to increase or decrease, depending on the direction of motion. By comparing the beat frequencies obtained from chirps of positive and negative slopes, it is thus possible to extract both the range and the velocity of the target.

Sensors for direct time-of-flight (dToF) depth measurement typically include one or more laser emitters, such as vertical-cavity surface-emitting lasers (VCSELs), and an array of single-photon detectors, such as single-photon avalanche diodes (SPADs). The emitter or emitters direct light pulses toward a target scene, and the detectors output electrical pulses in response to incident photons that have been reflected from the scene. The timespans between an emitted light pulse and the resulting electrical pulses are indicative of the time of flight of the photons and thus of the distances to the points in the scene from which the photons were reflected.

U.S. Patent Application Publication 2022/0404475, whose disclosure is incorporated herein by reference, describes a single-chip optical transceiver in which three silicon wafers are stacked and bonded together. The device includes a first semiconductor die including at least one avalanche photodetector. A second semiconductor die is bonded to the rear surface of the first die and includes a photodetector receiver analog circuit coupled to the at least one avalanche photodetector and an emitter driver circuit configured to drive a pulsed optical emitter. A third semiconductor die is bonded to the rear surface of the second die and includes logic circuits coupled to control the photodetector receiver analog circuit and the emitter driver circuit and to receive and process the electrical pulses output by the at least one avalanche photodetector.

The terms “light” and “optical radiation” are used interchangeably in the present description and in the claims to refer to electromagnetic radiation in any of the visible, infrared, and ultraviolet spectral ranges.

### SUMMARY

Embodiments of the present invention that are described hereinbelow provide improved apparatus and methods for optical sensing.

There is therefore provided, in accordance with an embodiment of the invention, an optoelectronic device, which includes a first semiconductor die, having first and second surfaces and including a first array of transceiver elements. Each transceiver element includes an optical transducer, configured to direct outgoing coherent optical radiation through the first surface toward a target and to receive incoming optical radiation that has been reflected from the target and is incident on the first surface. A single-photon optical detector is configured to output electrical pulses in response to photons of the incoming optical radiation. A waveguide is coupled to convey the incoming optical radiation from the optical transducer to the single-photon optical detector. A second semiconductor die is bonded to the second surface of the first semiconductor die and includes a second array of logic circuits, which are coupled to receive and process the electrical pulses output by the single-photon optical detectors in corresponding ones of the transceiver elements.

In some embodiments, the first and second semiconductor dies respectively include first and second silicon substrates. In a disclosed embodiment, the first semiconductor die includes one or more layers of a transparent dielectric material overlying the first silicon substrate, and the waveguide is embedded in the transparent dielectric material. In one embodiment, the transparent dielectric material includes silicon dioxide (SiO₂). Additionally or alternatively, the waveguide includes an optical material selected from a group of optical materials consisting of silicon and silicon nitride.

In some embodiments, the first silicon substrate is bonded to the second semiconductor die, such that the transparent dielectric material is at the first surface of the first semiconductor die. In a disclosed embodiment, the logic circuits are electrically connected to the single-photon optical detectors by through-silicon vias (TSVs) extending through the first silicon substrate.

Additionally or alternatively, the transparent dielectric material is bonded to the second semiconductor die, such that the first silicon substrate is at the first surface of the first semiconductor die and contains a transparent aperture overlying the optical transducer.

In one embodiment, the single-photon optical detector includes silicon germanium (SiGe).

In some embodiments, the single-photon optical detector includes a single-photon avalanche diode (SPAD). In a disclosed embodiment, the first semiconductor die includes a quenching circuit for the SPAD.

In one embodiment, the single-photon detector is disposed in proximity to the second surface of the first semiconductor die, and the waveguide is disposed between the single-photon detector and the first surface of the first semiconductor die. Alternatively, the single-photon detector is disposed in proximity to the first surface of the first semiconductor die, and the waveguide is disposed between the single-photon detector and the second surface of the first semiconductor die.

In a disclosed embodiment, the first semiconductor die includes an opaque shield layer positioned to prevent ambient optical radiation that is incident on the first surface from impinging directly the single-photon detector.

Additionally or alternatively, the waveguide is positioned to convey the incoming optical radiation into a first side of the single-photon optical detector, and the device includes a reflective layer positioned in proximity to a second side of the single-photon optical detector, opposite the first side, so as to reflect a part of the incoming optical radiation that has passed through the single-photon optical detector back into the single-photon optical detector.

In a disclosed embodiment, the optical transducer includes a first grating coupler, and the waveguide includes a second grating coupler configured to direct the incoming optical radiation from the waveguide to the single-photon optical detector.

In some embodiments, when the coherent optical radiation includes pulsed radiation, the logic circuits are configured to generate histograms of times of arrival of the photons. Additionally or alternatively, when the coherent optical radiation includes frequency-modulated continuous-wave (FMCW) radiation, the logic circuits are configured to generate digital waveforms indicative of a beat frequency of the photons.

In some embodiments, the coherent optical radiation includes frequency-modulated continuous-wave (FMCW) radiation, wherein the single-photon optical detector is coupled to receive a mixture of the incoming optical radiation with a local beam of the coherent optical radiation, and wherein the logic circuits are configured to compute counts the electrical pulses output by the single photon detector in response to the mixture of the optical radiation. In a disclosed embodiment, the device includes at least a first optical bus coupled to convey the outgoing coherent optical radiation from a laser to the transceiver elements and a second optical bus coupled to convey the local beam from the laser to the transceiver elements.

In some embodiments, the device includes a laser, which is configured to generate the outgoing coherent optical radiation, and at least one optical bus coupled to convey the outgoing coherent optical radiation from the laser to the transceiver elements. In a disclosed embodiment, the waveguide in each transceiver element is coupled to convey the outgoing coherent optical radiation from the at least one optical bus to the optical transducer in the transceiver element for output toward the target.

Additionally or alternatively, the at least one optical bus includes at least one network of optical buses, wherein the at least one network is configured as a tree with branches connected to respective rows of the transceiver elements in the first array. In one embodiment, the at least one network includes multiple networks of optical buses, each of the multiple networks coupled to receive the outgoing coherent optical radiation from a different, respective laser and including a respective tree connected to a respective subset of the rows of the transceiver elements.

In some embodiments, the laser includes a semiconductor laser chip, which is mounted on the first surface of the first semiconductor die. In a disclosed embodiment, the laser is configured to emit the outgoing coherent optical radiation through side of the semiconductor laser chip facing the first surface of the first semiconductor die, and the second semiconductor die includes a drive circuit for the laser. The first semiconductor die includes an optical coupler configured to couple the outgoing coherent optical radiation into the at least one optical bus, electrical pads, which are disposed on the first surface of the first semiconductor die and connected to the semiconductor laser chip, and at least one via passing through the first semiconductor die and coupled to convey a drive current from the drive circuit to the electrical pads.

There is also provided, in accordance with an embodiment of the invention, an optoelectronic device, which includes a first semiconductor die, having first and second surfaces and including at least one single-photon optical detector, configured to output electrical pulses in response to photons of incoming optical radiation that has been reflected from a target and is incident on the first surface. A laser, which has first and second sides, is mounted on the first surface of the first semiconductor die so as to direct an outgoing beam of coherent optical radiation from the first side of the laser toward the target and to direct a local beam of the coherent optical radiation from the second side of the laser toward the first surface. A waveguide runs along the first surface of the first semiconductor die and includes a first optical transducer configured to couple the local beam from the laser into the waveguide and at least one second optical transducer configured to couple a part of the local beam out of the waveguide toward the at least one single-photon optical detector. A second semiconductor die is bonded to the second surface of the first semiconductor die and includes logic circuits, which are coupled to receive and process the electrical pulses output by the at least one single-photon optical detector.

In a disclosed embodiment, the at least one single-photon optical detector includes an array of two or more optical detectors, and the at least one second optical transducer includes multiple optical transducers configured to couple respective parts of the local beam out of the waveguide toward the two or more optical detectors.

Additionally or alternatively, the laser includes a vertical-cavity emitter, which is mounted with the second side of the laser facing toward the first surface of the first semiconductor die.

In a disclosed embodiment, the first and second optical transducers include grating couplers.

Additionally or alternatively, the device includes at least one microlens disposed on the first surface of the first semiconductor die over the at least one single-photon optical detector.

There is additionally provided, in accordance with an embodiment of the invention, a method for producing an optoelectronic device. The method includes providing a first semiconductor die, having first and second surfaces and including a first array of transceiver elements. Each transceiver element includes an optical transducer, configured to direct outgoing coherent optical radiation through the first surface toward a target and to receive incoming optical radiation that has been reflected from the target and is incident on the first surface and a single-photon optical detector, configured to output electrical pulses in response to photons of the incoming optical radiation. A waveguide is coupled to convey the incoming optical radiation from the optical transducer to the single-photon optical detector. A second semiconductor die is bonded to the second surface of the first semiconductor die. The second semiconductor die includes a second array of logic circuits to receive and process the electrical pulses output by the single-photon optical detectors in corresponding ones of the transceiver elements.

The present invention will be more fully understood from the following detailed description of the embodiments thereof, taken together with the drawings in which:

### BRIEF DESCRIPTION OF THE DRAWINGS

FIG. 1 is a schematic side view of an optoelectronic device, in accordance with an embodiment of the invention;

FIG. 2 is a schematic frontal view of array of transceiver elements, in accordance with an embodiment of the invention;

FIG. 3 is a schematic detail view of one of the transceiver elements in the array of FIG. 2, in accordance with an embodiment of the invention;

FIGS. 4A and 4B are schematic electrical diagrams showing details of the electrical components of transceiver elements in the array of FIG. 2, along with associated logic circuits, in accordance with embodiments of the invention;

FIG. 5 is a schematic frontal view of array of transceiver elements, in accordance with another embodiment of the invention;

FIG. 6 is a schematic detail view of one of the transceiver elements in the array of FIG. 5, in accordance with an embodiment of the invention;

FIGS. 7, 8, 9 and 10 are schematic sectional views of optical transceiver elements and associated logic circuits, in accordance with embodiments of the invention;

FIG. 11 is a schematic sectional view of a laser input module, in accordance with an embodiment of the invention;

FIG. 12 is a block diagram that schematically illustrates a logic circuit in an optoelectronic device, in accordance with an embodiment of the invention;

FIG. 13 is a block diagram that schematically illustrates a logic circuit in an optoelectronic device, in accordance with an alternative embodiment of the invention; and

FIG. 14 is a schematic sectional view of an optical transceiver element and associated logic circuits, in accordance with an alternative embodiment of the invention.

### DETAILED DESCRIPTION

### Overview

Because of the complexity, size, and cost of the transmitters and receivers that are used in coherent sensing, FMCW depth sensing systems typically use a single transmitter and a single receiver (or a small number of transmitters and receivers), whose fields of view are scanned over a scene of interest. There is a need for integrated coherent transceiver arrays and modules with reduced overall size and cost, which are capable of collecting depth data simultaneously from multiple points in a scene.

Embodiments of the present invention that are described herein address this problem using stacked semiconductor dies: a first die comprising an array of optical transceiver elements, for transmitting and receiving coherent optical radiation to and from respective points on a target; and a second die, comprising an array of logic circuits, for controlling the optical transceiver elements and processing their outputs. The use of stacked dies makes it possible to apply two different, respective fabrication processes, including photonic integrated circuit (PIC) components in the first die and high-density logic components, such as complementary metal oxide semiconductor (CMOS) components, in the second die. In the embodiments that are described hereinbelow, both dies comprise respective silicon substrates, which are bonded together electrically and mechanically. Alternatively or additionally, at least the first die may comprise other semiconductor materials.

In the disclosed embodiments, the optical transceiver elements comprise single-photon optical detectors, such as SPADs, which output electrical pulses in response to photons of incoming optical radiation. In some embodiments, the SPADs are used in conjunction with pulsed radiation transmitted by the transceiver elements for detecting the times of arrival of photons reflected from the target, for the purpose of depth sensing based on dToF. In other embodiments, the SPADs are used in conjunction with FMCW coherent radiation transmitted by the transceiver elements for detecting beat frequencies due to mixing of the reflected photons with a local beam, for example as described in the above-mentioned U.S. patent application Ser. No. 18/623,080. The logic circuits in the second die may be configured to support either or both of these sensing modes, i.e., both dToF and FMCW sensing. This dual-use configuration supports versatile depth sensing capabilities in a compact, low-cost package.

Thus, in the embodiments of the present invention that are described hereinbelow, an optoelectronic device comprises a first semiconductor die, comprising an array of transceiver elements, and a second semiconductor die, comprising an array of logic circuits. The device transmits and receives optical radiation toward and from a target through one surface of the first semiconductor die (which is referred to herein for convenience as the front surface), while the other (rear) surface of the first semiconductor dies is bonded to the second semiconductor die.

Each transceiver element in the first semiconductor die comprises an optical transducer, which directs outgoing coherent optical radiation through the front surface toward the target and receives incoming optical radiation that has been reflected from the target and is incident on the front surface. In the present description and in the claims, the term “optical transducer” refers to an optical element that converts a guided wave of optical radiation from a waveguide to a propagating wave in a bulk medium (including free space) and/or vice versa. In the embodiments that are described below, the optical transducers in the transceiver elements comprise grating couplers; but alternatively, other types of optical transducers may be used.

Each transceiver element also comprises a single-photon optical detector, which outputs electrical pulses in response to photons of the incoming optical radiation, as well as a waveguide, which conveys the incoming optical radiation from the optical transducer to the single-photon optical detector. Each of the logic circuits in the second semiconductor die receives and processes the electrical pulses output by the single-photon detector in one or more corresponding transceiver elements. The logic circuits may each be coupled to a single, respective transceiver element, or they may process the pulses output collectively by a group of neighboring transceiver elements to achieve a higher signal/noise ratio (SNR) and more efficient use of processing resources.

### System Description

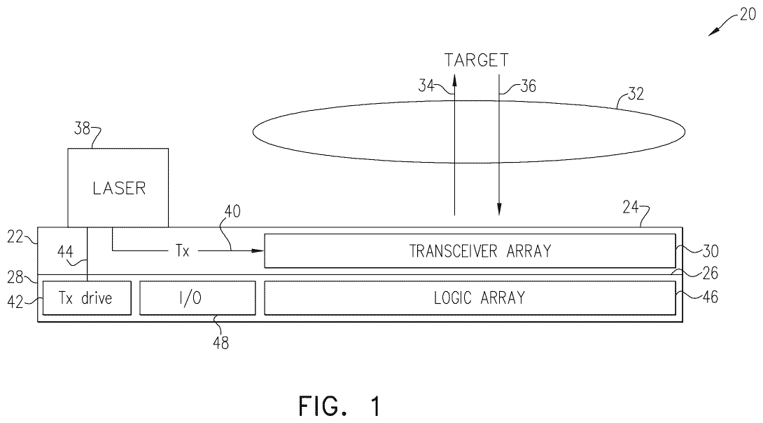

FIG. 1 is a schematic side view of an optoelectronic device 20, in accordance with an embodiment of the invention. Device 20 comprises a first semiconductor die 22, having a front surface 24, which faces toward a target, and a rear surface 26, which is bonded to a second semiconductor die 28.

First semiconductor die 22 comprises an array 30 of transceiver elements, comprising single-photon optical detectors and other components, as described with reference to the figures that follow. The transceiver elements in array 30 direct outgoing coherent optical radiation 34 through front surface 24 via optics 32 toward a target and receive incoming optical radiation 36 that has been reflected from the target and is incident on front surface 24. (For coherent sensing applications, the transceiver elements also receive a local beam, as described further hereinbelow, as well as ambient radiation.) In the pictured embodiment, optics 32 image the target onto transceiver array 30, wherein the same lens (simple or compound) serves the entire array. This shared-lens scheme is useful in minimizing the size and cost of device 22.

A laser 38 generates the outgoing coherent optical radiation and conveys the outgoing coherent optical radiation via an optical bus 40 on die 22 to array 30 for transmission by the transceiver elements toward the target. In the pictured embodiments, laser 38 comprises a semiconductor laser chip, which is mounted on front surface 24 of first semiconductor die 22. A drive circuit 42 in second semiconductor die 28 conveys a drive current to laser 38 through at least one via 44 passing through first semiconductor die 22. In the embodiments described below, laser 38 comprises a vertically emitting semiconductor laser, such as a vertical-cavity surface-emitting laser (VCSEL) or a vertical external-cavity surface-emitting laser (VECSEL). Alternatively, laser 38 may comprise an edge-emitting semiconductor laser or any other suitable type of laser, which may or may not be mounted on front surface 24. In alternative embodiments, device may comprise multiple lasers, as well as multiple optical buses.

Second semiconductor die 28 also comprises an array 46 of logic circuits, which receive and process the electrical pulses output by the single-photon detectors in corresponding transceiver elements. The logic circuits are described with reference to the figures that follow. Each logic circuit outputs a histogram or digital waveform representing the timing of the electrical pulses output by the corresponding transceiver element. An input/output (I/O) circuit 48 outputs the histograms or waveforms to an external processor (not shown), which may process these outputs to generate a depth map of the target. I/O circuit 48 may also receive inputs from the processor or another controller to control the operation of device 20.

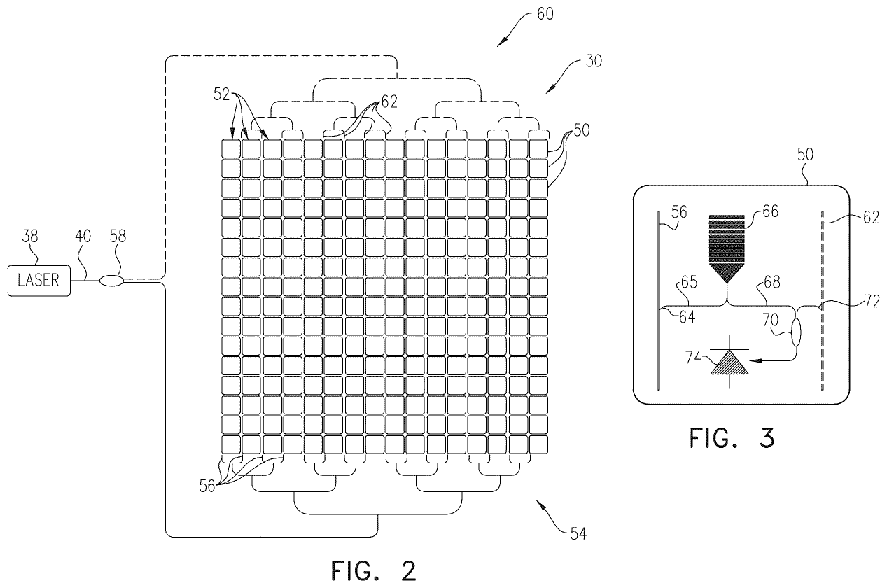

FIG. 2 is a schematic frontal view of array 30 of transceiver elements 50, in accordance with an embodiment of the invention. Transceiver elements are arranged in multiple rows 52 (which may equivalently be referred to as columns, since the orientation of array 30 is arbitrary). Bus 40 conveys the outgoing coherent radiation from laser 38 to a network 54 of optical buses. Network 54 is configured as a tree, with branches 56 connected to respective rows of the transceiver elements 50 in array 30. In this embodiment, network 54 contains no switches, meaning that all the rows of transceiver elements simultaneously receive the coherent optical radiation that is output by laser 38, and all the transceiver elements direct their respective shares of the outgoing coherent optical radiation toward the target.

This switchless architecture is useful in reducing the size of device 20 and avoiding power losses in network 54. Because all transceiver elements 50 acquire signals simultaneously, it is possible to shut down device 20 almost entirely once signal acquisition has been completed. Alternatively, the laser radiation can be distributed to the transceiver elements via other sorts of network topologies, which may include optical switches.

For purposes of FMCW sensing, transceiver elements 50 use a part of the coherent optical radiation that is output by laser 38 as a local beam, for mixing with the incoming optical radiation that has been reflected from the target. In the embodiment that is shown in FIG. 2, a splitter 58 splits off a small part of the laser beam energy to an additional network 60 of optical buses. Network 60, like network 54, is configured as a tree, with branches 62 that supply the local beam to respective rows of transceiver elements 50.

FIG. 3 is a schematic detail view of one of transceiver elements 50 in array 30, in accordance with an embodiment of the invention. An optical power tap 64 extracts a part of the outgoing coherent optical radiation from branch 56 of network 54 and conveys the extracted radiation via a transmit waveguide 65 to an optical grating coupler 66, which serves as the optical transducer in transceiver element 50. Grating coupler 66 directs the outgoing coherent optical radiation through the front surface 24 of die 22 (FIG. 1) toward the target and directs incoming optical radiation that has been reflected from the target and is incident on front surface 24 into a receive waveguide 68.

The use of grating coupler 66 as the optical interface between transceiver element 50 and the target is advantageous in enhancing the useful signal levels of the transceiver element and reducing its sensitivity to ambient radiation. Grating couplers 66 can be designed for highly directional coupling of the mode that is guided through transmit waveguide 65 via a small effective aperture toward the target, and similarly to couple radiation reflected back from the target through this aperture into receive waveguide 68. As a result of the small aperture and mode selectivity of grating coupler 66, transceiver element 50 rejects most ambient light and can therefore achieve higher SNR than would be possible if SPAD 74 were exposed directly to incoming optical radiation that is incident on device 20.

For FMCW sensing, a local beam tap 72 extracts a part of the local beam of coherent optical radiation from branch 62 of network 60. An optical mixer 70 mixes this part of the local beam with incoming optical radiation from receive waveguide 68. A SPAD 74 receives the mixture of the incoming optical radiation with the local beam and outputs electrical pulses in response to the photons that it receives. The output of SPAD 74 is processed to extract beat frequencies, as described further hereinbelow.

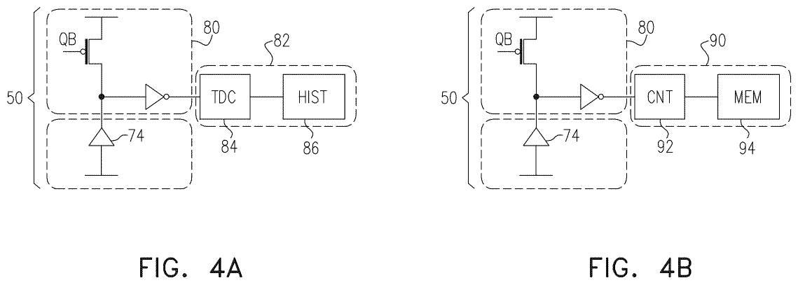

FIGS. 4A and 4B are schematic electrical diagrams showing details of the electrical components of transceiver elements 50, along with associated logic circuits 82 and 90, respectively, in accordance with embodiments of the invention. Each transceiver element 50 comprises a respective SPAD 74 with associated bias and quenching circuits 80. Bias and quenching circuits 80 comprise transistors, which may be fabricated as part of transceiver array 30 in die 22. Alternatively, some or all of the elements of the bias and quenching circuits may be formed in die 28.

Logic circuits 82 and 90 are formed in die 28. Logic circuit 82 is designed for use in dToF sensing, using pulsed optical radiation, while logic circuit 90 is designed for use in FMCW sensing. Alternatively, a single logic circuit may be configurable for both types of sensing, as described further hereinbelow.

Logic circuit 82 comprises a time-to-digital converter (TDC), which outputs digital values indicative of the times of arrival of photons, based on the timing of electrical pulses output by SPAD 74 relative to the time of emission of each outgoing optical pulse. A histogram memory 86 assembles a histogram of the times of arrival. Typically, the peak of the histogram is indicative of the time of flight of the photons, and hence the distance to the target.

Logic circuit 90 comprises a counter 92, which counts the electrical pulses output by SPAD 74 in multiple, successive time bins as the frequency of the laser beam is swept over a certain chirp range. The counts define a digital temporal waveform, which is stored in a buffer memory 94. This temporal waveform can then be transformed to the frequency domain, and the frequency spectrum can be analyzed to find a peak corresponding to the beat frequency of the mixed optical signal. Because the output of SPAD 74 is essentially digital, no transimpedance amplifier is needed at the output, and the SPAD output signal is essentially free of common noise sources affecting analog signals such as thermal and flicker noise. The benefits of this pulsed sensing arrangement in FMCW LIDAR and methods for processing and analyzing the SPAD output signal are described in detail in the above-mentioned U.S. Provisional Patent Application 63/515,348. The beat frequency is indicative of the distance to the target and may also indicate the radial velocity of the target relative to device 20.

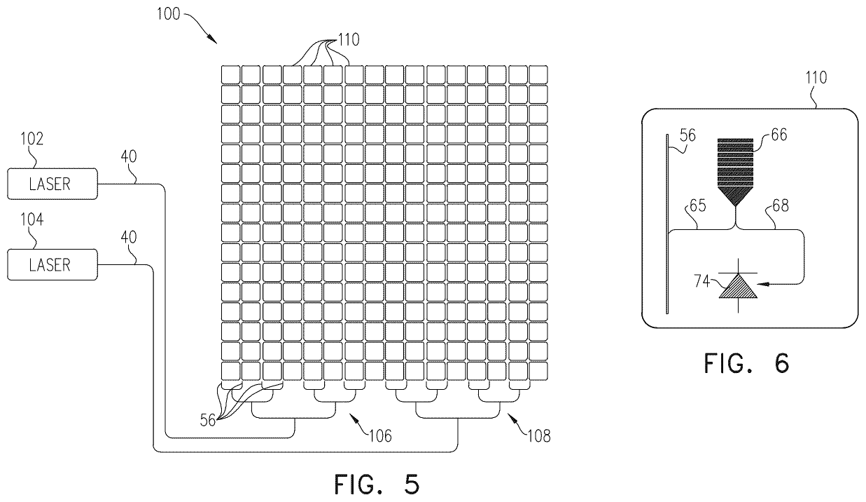

Reference is now made to FIGS. 5 and 6, which schematically illustrate an array 100 of transceiver elements 110, in accordance with another embodiment of the invention. FIG. 5 is a frontal view of array 100, while FIG. 6 is a detail view of one of transceiver elements 110.

In this embodiment, array 100 is served by two networks 106, 108 of optical buses, each of which receives outgoing coherent optical radiation from a different, respective laser 102 or 104. Each network 106, 108 comprises a respective tree, which is connected to provide the outgoing coherent optical radiation to a respective subset of the of rows transceiver elements 110. Alternatively, a larger number of lasers and respective optical networks may be used. Further alternatively, a single laser may be time-multiplexed among multiple optical networks of this sort. The use of multiple lasers and optical networks is useful in reducing the power demands on each of lasers and/or increasing the power of the outgoing optical radiation directed by the device toward the target.

In contrast to the embodiment of FIGS. 2 and 3, array 100 does not include a separate network of optical buses for distribution of the local beam. Rather, stray reflections and scatter within transceiver element 110 will convey a small fraction of the outgoing coherent optical radiation from transmit waveguide 65 into receive waveguide 68. This stray fraction serves as the local beam, mixing in receive waveguide 68 with the incoming optical radiation received by grating coupler 66. Because the output of SPAD 74 is essentially free of thermal noise, this small, stray local beam can be sufficient by itself to give an appreciable beat signal in the output of the SPAD.

### Optical Transceiver Elements

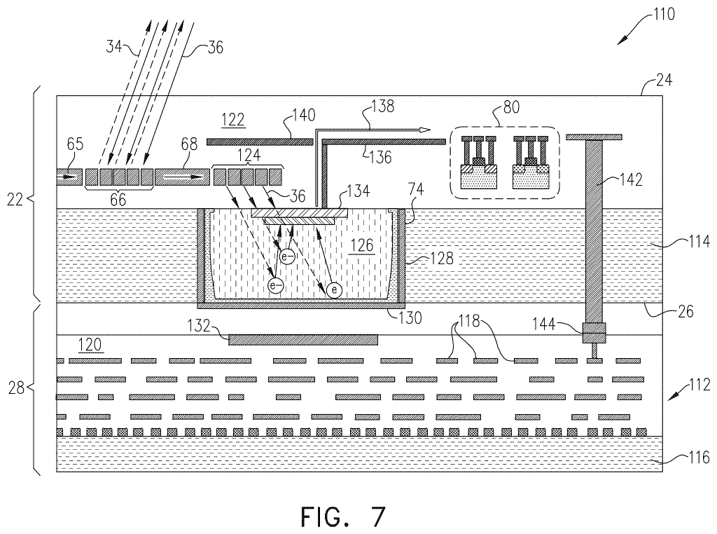

FIG. 7 is a schematic sectional view of transceiver element 110 and associated logic circuits 112, in accordance with an embodiment of the invention. The physical elements shown in FIG. 7 are labeled with the same indicator numbers as the corresponding functional elements that were in the preceding figures. In this embodiment, dies 22 and 28 comprise respective silicon substrates 114 and 116. Logic circuits 112 are fabricated on substrate 116 by a CMOS process, for example, with multiple overlying layers of metal interconnects 118 interleaved with layers 120 of SiO₂.

Die 22 comprises multiple layers of a transparent dielectric material 122, such as SiO₂, in which waveguides 65 and 68 are embedded. Die 22 is oriented in this embodiment with dielectric material 122 at front surface 24, while die 28 is bonded to silicon substrate 114 at rear surface 26 of die 22. Grating coupler 66 directs outgoing coherent optical radiation 34 from transmit waveguide 65 toward the target and conveys incoming optical radiation 36 from the target into receive waveguide 68. In this embodiment, the coherent optical radiation has a relatively short wavelength, for example around 940 nm, and waveguides 65 and 68 comprise silicon nitride (SiN). SPAD 74 is formed in silicon substrate 114 in proximity to rear surface 26, while waveguides 65 and 68 are formed in dielectric material 122 at a level that is between SPAD 74 and front surface 24. An additional grating coupler 124 at the end of receive waveguide 68 directs the incoming optical radiation from waveguide 68 to SPAD 74.

SPAD 74 comprises heavily doped silicon 126, which is contained between metal sidewalls 128 and a metal base 130, comprising tungsten (W), for example, to serve as the anode terminal of the SPAD. Incoming optical radiation 36, mixed with a local beam (not shown in this figure), enters through the front side of SPAD 76 and gives rise to photoelectrons in doped silicon 126. Metal base 130 serves as a reflective layer on the rear side of SPAD 76 in order to reflect photons of incoming optical radiation 36 that have passed through SPAD 76 back into doped silicon 126, thus enhancing the detection efficiency of the SPAD. Alternatively or additionally, a metal reflector 132 may be patterned for this purpose among metal interconnects 118 near the front side of die 28.

A cathode 134 of SPAD 74 is connected by a conductor 136 to bias and quenching circuits 80 and outputs electrical pulses 138 in response to the photons that are absorbed in doped silicon 126. The metal layer used to form conductor 136 is also patterned to create an opaque shield layer 140, which prevents ambient optical radiation that is incident on front surface 24 from impinging directly on SPAD 74. The output signal from SPAD 74 is coupled through bias and quenching circuits 80 to logic circuits 112 by a through-silicon via (TSV) 142. TSV 142 passes through silicon substrate 114 and is connected to logic circuits 112, for example by a copper-to-copper bond 144.

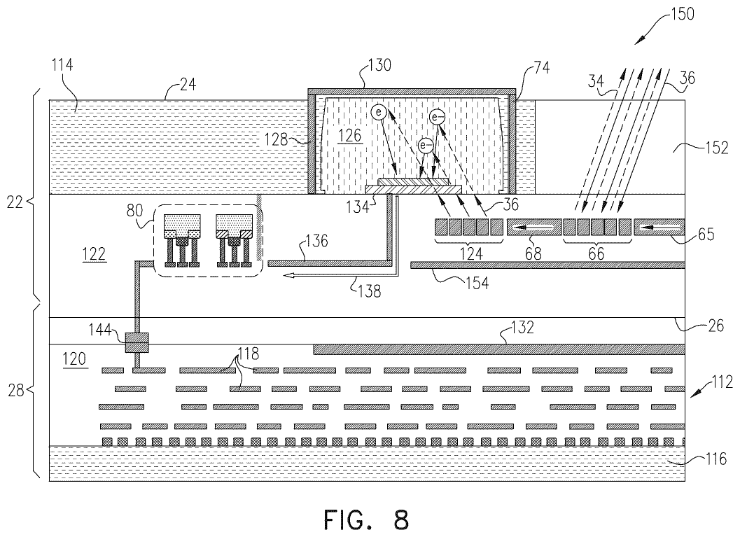

FIG. 8 is a schematic sectional view of a transceiver element 150 and associated logic circuits 112, in accordance with another embodiment of the invention. Transceiver element 150 is similar in structure and functionality to transceiver element 110, shown in FIG. 7, and may be used in place of transceiver element 110, for example in array 100 (FIG. 5). Components of transceiver element 150 are labeled with the same indicator numbers as the corresponding components of transceiver element 110 and will not be described further except as they pertain to the differences between the transceiver elements.

In transceiver element 150, die 22 is flipped upside down relative to its orientation in transceiver element 110. In other words, silicon substrate 114 and SPAD 74 are located at front surface 24 of die 22, and SPAD 74 receives photons that are directed toward the SPAD from within transceiver element 110. To accommodate this orientation, receive waveguide 64 is located between SPAD 74 and rear surface 26 of die 22. Dielectric material 122 (typically comprising SiO₂) on die 22 is bonded to the outer layer 120 of SiO₂ on die 28. An aperture 152 is etched through substrate 114 to allow outgoing coherent optical radiation 34 to pass out of grating coupler 66 toward the target and to allow incoming optical radiation reflected from the target to reach grating coupler 66. Aperture 152 may be filled with a suitable transparent material, such as SiO₂. Metal base 130 and shield layer 140 block ambient light photons from reaching the interior of SPAD 74.

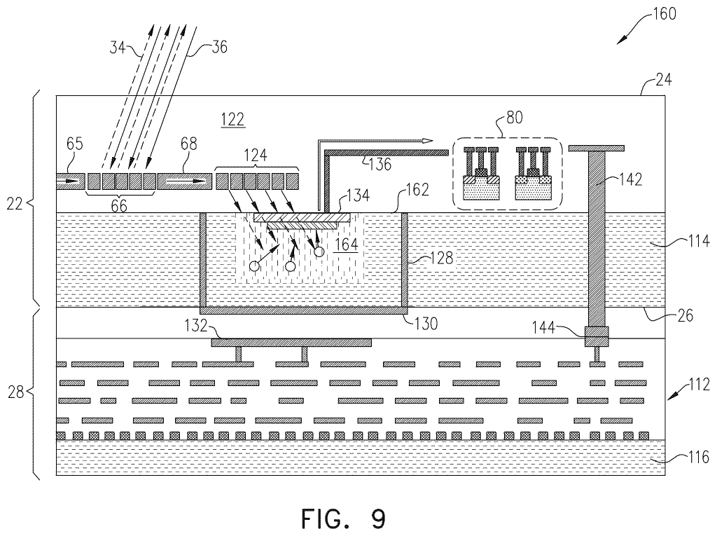

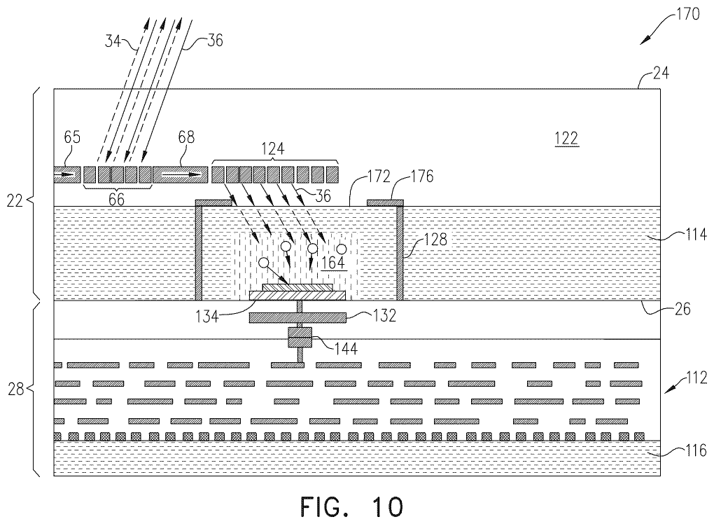

FIG. 9 is a schematic sectional view of a transceiver element 160 and associated logic circuits 112, in accordance with yet another embodiment of the invention. Transceiver element 160 is similar in structure and functionality to transceiver element 110, shown in FIG. 7, but is designed to transmit and sense infrared radiation at a longer wavelength, for example around 1300 nm. To sense wavelengths in this range, transceiver element 160 comprises a silicon germanium (SiGe) SPAD 162, containing germanium 164. Waveguides 65 and 68, as well as grating couplers 66 and 124, comprise a suitable waveguide material, such as amorphous silicon, which is transparent to optical radiation in the longer wavelength range.

In an alternative embodiment (not shown in the figures), die 22 containing SiGe SPAD 162 is flipped upside down relative to its orientation in transceiver element 160. The modifications in this case are similar to those in FIG. 8.

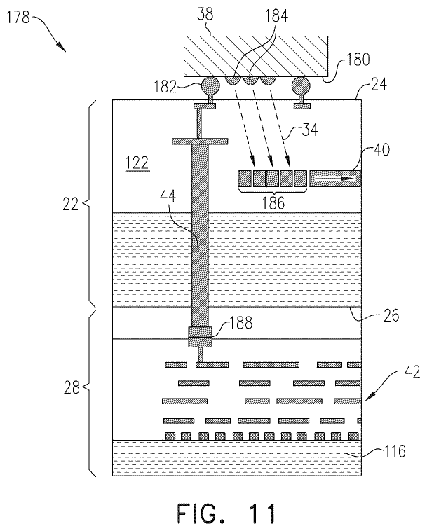

FIG. 10 is a schematic sectional view of a transceiver element 170 and associated logic circuits 112, in accordance with a further embodiment of the invention. As in the preceding embodiment, transceiver element 170 is designed for operation at longer infrared wavelengths, for example around 1300 nm, and comprises a SiGe SPAD 172, comprising germanium 164, surrounded by silicon. In this case, however, SPAD 172 is fabricated by a backside integration (BSI) process, in which germanium 164 is deposited through back surface 26 of die 22. SPAD 172 is connected electrically via bond 144 directly to logic circuits 112 in die 28. Incoming optical radiation 36 is directed by grating coupler 124 through the rear side of SPAD 172 and thus passes through the surrounding silicon to impinge on germanium 164. An opaque shield 176, for example comprising a metal layer, blocks ambient and scattered radiation from entering the SPAD.

### Laser Input

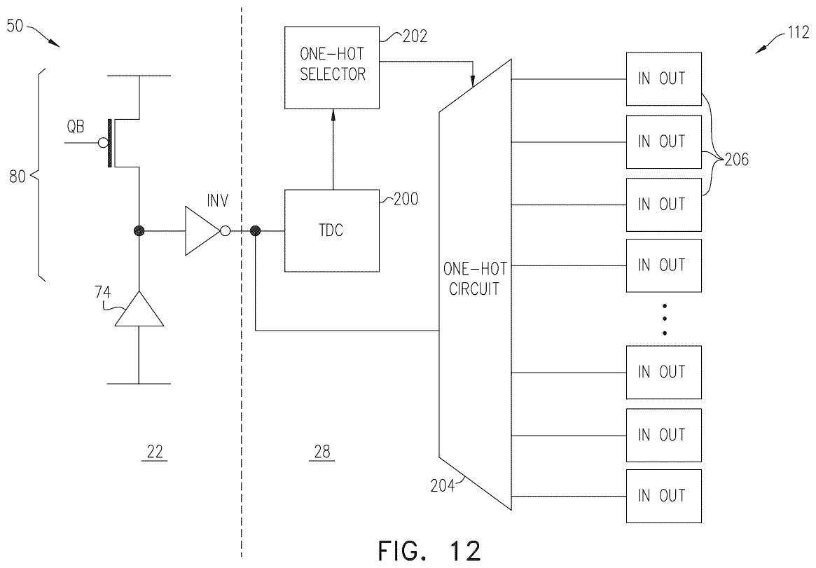

FIG. 11 is a schematic sectional view of a laser input module 178, which may be incorporated in optoelectronic device 20 (FIG. 1), in accordance with an embodiment of the invention. Laser 38 in module 178 is assumed to be a back-emitting VCSEL chip, which emits outgoing coherent optical radiation 34 through a surface 180 that faces front surface 24 of die 22. The VCSEL chip is mounted on and soldered to electrical pads 182, which are formed on front surface 24, over dielectric material 122 on die 22. TSV 44 connects laser 38 to drive circuit 42 in die 28 via a metal-metal bond 188.

Outgoing coherent optical radiation 34 from laser 38 passes through front surface 24 of die 22, and an optical coupler 186, such as a grating coupler, couples radiation 34 into optical bus 40 for distribution to the transceiver elements. Microlenses 184 may be formed on surface 180 of the VCSEL chip to steer the laser beam toward coupler 186.

The use of a VCSEL as laser 38 in the configuration shown in FIG. 11 is advantageous in that it is compact and easy to align with the photonic components in die 22. The VCSEL may be driven to emit either pulsed radiation or modulated CW radiation, depending on the sensing mode to be applied by the device. The VCSEL may be mounted in similar fashion on the outer surface of die 22 in the flipped orientation of FIG. 8. Alternatively, as noted earlier, device 20 may comprise other sorts of lasers, such as VECSELs or edge-emitting lasers.

### Logic Circuits

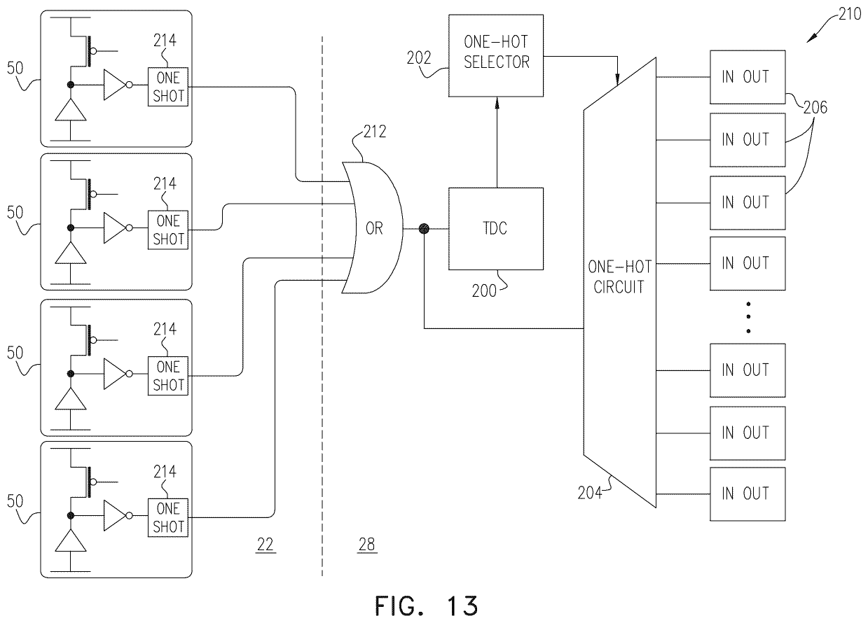

FIG. 12 is a block diagram that schematically illustrates one logic circuit 112 in device 20 (FIG. 1), in accordance with an embodiment of the invention. In this embodiment, logic circuit 112 processes the electrical pulses that are output by a single, corresponding transceiver element 50, which comprises SPAD 74 and bias and quenching circuits 80, as described above. Logic circuit 112 supports both dToF sensing, for which laser 38 emits pulsed radiation, and FMCW sensing, for which laser 38 emits frequency-chirped CW radiation. Thus, device 20 can be used in either sensing mode by appropriate choice and configuration of laser 38 and logic circuits 112.

Circuit 112 comprises a time-to-digital converter (TDC) 200, which controls a multiplexer 204 via a one-hot selector 202 to write pulse counts to multiple memory buffers 206. Each buffer 206 represents a particular time bin. In dToF sensing, TDC 200 counts the time delay of each electrical pulse output by transceiver element 50 relative to the laser output pulse and instructs one-hot selector 202 to select the buffer 206 corresponding to the digital value of the time delay. Thus, multiplexer 204 will increment the pulse count in the bin corresponding to the time of arrival of the corresponding photon. The counts that accumulate in the array of buffers 206 create a histogram of the times of flight of the photons reflected from the target.

In FMCW sensing, on the other hand, TDC 200 simply drives one-hot selector 202 to cycle through buffers 206 incrementally as a function of time over the period of each frequency chirp. Thus, each output pulse from transceiver element 50 will increment the count in a corresponding time bin within the chirp. The counts in the array of buffers 206 in this case define a digital temporal waveform, which can be transformed to the frequency domain and analyzed to find a spectral peak corresponding to the beat frequency that results from mixing of the incoming optical radiation with the local beam.

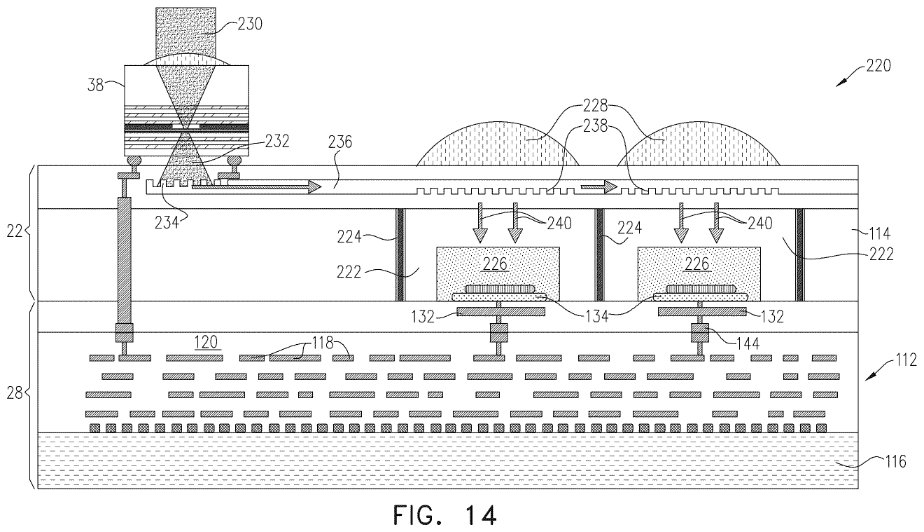

FIG. 13 is a block diagram that schematically illustrates a logic circuit 210 that can be used in device 20 (FIG. 1), in accordance with an alternative embodiment of the invention. Logic circuit 210 is similar in its construction and operation to logic circuit 112, but differs in that logic circuit 210 collectively processes the electrical pulses that are output by a group of adjacent transceiver elements 50. This group is treated in device 20 as a single “super pixel,” which has the advantages of improved SNR, as well as reduced power consumption and device size due to more efficient use of processing resources, at the cost of poorer spatial resolution. Although FIG. 13 shows a super pixel containing four transceiver elements 50, the principles of this embodiment may be applied to larger or smaller super pixels.

In logic circuit 210, an OR gate 212 combines the electrical pulses that are output by transceiver elements 50 into a single pulse train for input to TDC 200 and multiplexer 204. To reduce the likelihood of pulse collisions in the outputs different of transceiver elements, a one-shot pulse generator 214 sharpens the electrical pulses that are output by the SPADS. As in the preceding embodiment, logic circuit 210 will create a histogram or digital waveform in buffers 206, depending on the sensing mode of device 20.

### Bistatic Transceiver Element

FIG. 14 is a schematic sectional view of a transceiver element 220 and associated logic circuits 112, in accordance with an alternative embodiment of the invention. Transceiver element 220 has some similarities in structure and functionality to the transceiver elements described above and may be used in an array. Certain components of transceiver element 220 are labeled with the same indicator numbers as the corresponding components of transceiver element 110 (FIG. 7) and will not be described further except as they pertain to the differences between the transceiver elements.

Unlike the transceiver elements described above, however, transceiver element 220 is bistatic, i.e., it has separate transmit and receive apertures, and it may include multiple SPADs 222 in semiconductor die 22. Although only two SPADs are shown in FIG. 14, transceiver element 220 may be expanded to include a larger number of SPADs in a linear array or in even a two-dimensional matrix array. Alternatively, transceiver element 220 may comprise only a single SPAD. SPADs 222 are separated from one another by deep trench isolation (DTI) channels 224, which may be filled with tungsten, for example. As in the embodiment of FIG. 10, SPADs 222 are SiGe components, including a germanium sensing element 226, fabricated in a BSI configuration. Alternatively, the principles of this embodiment may be implemented in a frontside configuration, as well as with silicon SPADs for sensing at shorter wavelengths. Microlenses 228 focus optical radiation from the target onto respective SPADs 222.

Laser 38 in this embodiment comprises a dual-sided VCSEL, which is mounted on the outer surface of semiconductor die 22. Laser 38 outputs a forward beam 230 toward the target and a reverse beam 232 (of much lower intensity) toward semiconductor die 22 to serve as the local beam. An optical transducer, such as a grating coupler 234, couples beam 232 into a waveguide 236, which runs along the outer surface of semiconductor die 22 and distributes the beam among SPADS 222. Other optical transducers, in the form of grating couplers 238, each extract a part of the energy propagating in waveguide 236 and thus direct respective local beams 240 toward SPADs 222. Microlenses 228 and grating couplers 238 are designed to match the electric field profile of the radiation collected from the target and received by SPADs to the optical mode of local beams 240.

The embodiments described above are cited by way of example, and the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An optoelectronic device, comprising:
a first semiconductor die, having first and second surfaces and comprising a first array of transceiver elements, each transceiver element comprising:
an optical transducer, configured to direct outgoing coherent optical radiation through the first surface toward a target and to receive incoming optical radiation that has been reflected from the target and is incident on the first surface;
a single-photon optical detector, configured to output electrical pulses in response to photons of the incoming optical radiation; and
a waveguide coupled to convey the incoming optical radiation from the optical transducer to the single-photon optical detector; and
a second semiconductor die, which is bonded to the second surface of the first semiconductor die and which comprises a second array of logic circuits, which are coupled to receive and process the electrical pulses output by the single-photon optical detectors in corresponding ones of the transceiver elements.

2. The device according to claim 1, wherein the first and second semiconductor dies respectively comprise first and second silicon substrates.

3. The device according to claim 2, wherein the first semiconductor die comprises one or more layers of a transparent dielectric material overlying the first silicon substrate, and wherein the waveguide is embedded in the transparent dielectric material.

4. The device according to claim 3, wherein the transparent dielectric material comprises silicon dioxide (SiO₂).

5. The device according to claim 3, wherein the waveguide comprises an optical material selected from a group of optical materials consisting of silicon and silicon nitride.

6. The device according to claim 3, wherein the first silicon substrate is bonded to the second semiconductor die, such that the transparent dielectric material is at the first surface of the first semiconductor die.

7. The device according to claim 6, wherein the logic circuits are electrically connected to the single-photon optical detectors by through-silicon vias (TSVs) extending through the first silicon substrate.

8. The device according to claim 3, wherein the transparent dielectric material is bonded to the second semiconductor die, such that the first silicon substrate is at the first surface of the first semiconductor die and contains a transparent aperture overlying the optical transducer.

9. The device according to claim 2, wherein the single-photon optical detector comprises silicon germanium (SiGe).

10. The device according to claim 1, wherein the single-photon optical detector comprises a single-photon avalanche diode (SPAD).

11. The device according to claim 10, wherein the first semiconductor die comprises a quenching circuit for the SPAD.

12. The device according to claim 1, wherein the single-photon detector is disposed in proximity to the second surface of the first semiconductor die, and wherein the waveguide is disposed between the single-photon detector and the first surface of the first semiconductor die.

13. The device according to claim 1, wherein the single-photon detector is disposed in proximity to the first surface of the first semiconductor die, and wherein the waveguide is disposed between the single-photon detector and the second surface of the first semiconductor die.

14. The device according to claim 1, wherein the first semiconductor die comprises an opaque shield layer positioned to prevent ambient optical radiation that is incident on the first surface from impinging directly on the single-photon detector.

15. The device according to claim 1, wherein the waveguide is positioned to convey the incoming optical radiation into a first side of the single-photon optical detector, and wherein the device comprises a reflective layer positioned in proximity to a second side of the single-photon optical detector, opposite the first side, so as to reflect a part of the incoming optical radiation that has passed through the single-photon optical detector back into the single-photon optical detector.

16. The device according to claim 1, wherein the optical transducer comprises a first grating coupler, and wherein the waveguide comprises a second grating coupler configured to direct the incoming optical radiation from the waveguide to the single-photon optical detector.

17. The device according to claim 1, wherein when the coherent optical radiation comprises pulsed radiation, the logic circuits are configured to generate histograms of times of arrival of the photons.

18. The device according to claim 17, wherein when the coherent optical radiation comprises frequency-modulated continuous-wave (FMCW) radiation, the logic circuits are configured to generate digital waveforms indicative of a beat frequency of the photons.

19. The device according to claim 1, wherein the coherent optical radiation comprises frequency-modulated continuous-wave (FMCW) radiation, wherein the single-photon optical detector is coupled to receive a mixture of the incoming optical radiation with a local beam of the coherent optical radiation, and wherein the logic circuits are configured to compute counts the electrical pulses output by the single photon detector in response to the mixture of the optical radiation.

20. The device according to claim 19, and comprising at least a first optical bus coupled to convey the outgoing coherent optical radiation from a laser to the transceiver elements and a second optical bus coupled to convey the local beam from the laser to the transceiver elements.

21. The device according to claim 1, and comprising a laser, which is configured to generate the outgoing coherent optical radiation, and at least one optical bus coupled to convey the outgoing coherent optical radiation from the laser to the transceiver elements.

22. The device according claim 21, wherein the waveguide in each transceiver element is coupled to convey the outgoing coherent optical radiation from the at least one optical bus to the optical transducer in the transceiver element for output toward the target.

23. The device according to claim 21, wherein the at least one optical bus comprises at least one network of optical buses, wherein the at least one network is configured as a tree with branches connected to respective rows of the transceiver elements in the first array.

24. The device according to claim 23, wherein the at least one network comprises multiple networks of optical buses, each of the multiple networks coupled to receive the outgoing coherent optical radiation from a different, respective laser and comprising a respective tree connected to a respective subset of the rows of the transceiver elements.

25. The device according to claim 21, wherein the laser comprises a semiconductor laser chip, which is mounted on the first surface of the first semiconductor die.

26. The device according to claim 25, wherein the laser is configured to emit the outgoing coherent optical radiation through a side of the semiconductor laser chip facing the first surface of the first semiconductor die, and wherein the second semiconductor die comprises a drive circuit for the laser, and wherein the first semiconductor die comprises:
an optical coupler configured to couple the outgoing coherent optical radiation into the at least one optical bus;
electrical pads, which are disposed on the first surface of the first semiconductor die and connected to the semiconductor laser chip; and
at least one via passing through the first semiconductor die and coupled to convey a drive current from the drive circuit to the electrical pads.

27. An optoelectronic device, comprising:
a first semiconductor die, having first and second surfaces and comprising at least one single-photon optical detector, configured to output electrical pulses in response to photons of incoming optical radiation that has been reflected from a target and is incident on the first surface;
a laser, which has first and second sides and is mounted on the first surface of the first semiconductor die so as to direct an outgoing beam of coherent optical radiation from the first side of the laser toward the target and to direct a local beam of the coherent optical radiation from the second side of the laser toward the first surface;
a waveguide running along the first surface of the first semiconductor die, and comprising a first optical transducer configured to couple the local beam from the laser into the waveguide and at least one second optical transducer configured to couple a part of the local beam out of the waveguide toward the at least one single-photon optical detector; and
a second semiconductor die, which is bonded to the second surface of the first semiconductor die and which comprises logic circuits, which are coupled to receive and process the electrical pulses output by the at least one single-photon optical detector.

28. The device according to claim 27, wherein the at least one single-photon optical detector comprises an array of two or more optical detectors, and wherein the at least one second optical transducer multiple optical transducers configured to couple respective parts of the local beam out of the waveguide toward the two or more optical detectors.

29. The device according to claim 27, wherein the laser comprises a vertical-cavity emitter, which is mounted with the second side of the laser facing toward the first surface of the first semiconductor die.

30. The device according to claim 27, wherein the first and second optical transducers comprise grating couplers.

31. The device according to claim 27, and comprising at least one microlens disposed on the first surface of the first semiconductor die over the at least one single-photon optical detector.

32. A method for producing an optoelectronic device, the method comprising:
providing a first semiconductor die, having first and second surfaces and comprising a first array of transceiver elements, each transceiver element comprising an optical transducer, configured to direct outgoing coherent optical radiation through the first surface toward a target and to receive incoming optical radiation that has been reflected from the target and is incident on the first surface and a single-photon optical detector, configured to output electrical pulses in response to photons of the incoming optical radiation;
coupling a waveguide to convey the incoming optical radiation from the optical transducer to the single-photon optical detector; and
bonding to the second surface of the first semiconductor die a second semiconductor die, which comprises a second array of logic circuits to receive and process the electrical pulses output by the single-photon optical detectors in corresponding ones of the transceiver elements.
